(19) United States
(12) Patent Application Publication
(10) Pub. No.: US 2003/0084392 A1
(43) Pub. Date: May 1, 2003

(54) Decoder and receiver using the same

(76) Inventors: Toshihiro Hattori, Okazaki-City (JP); Hideyuki Morita, Nishio-City (JP); Tsukie Uegaki, Kariya-City (JP)

Correspondence Address: HARNESS, DICKEY & PIERCE, P.L.C., P.O. BOX 828, BLOOMFIELD HILLS, MI, 48303, US

(21) Appl. No.: 10/278,515

(22) Filed: Oct. 23, 2002

(30) Foreign Application Priority Data
Oct. 24, 2001 (JP) 2001-326818

(51) Int. Cl. H03M 7/20; H03M 13/00

(52) U.S. Cl. 714/752

(57) ABSTRACT

A turbo decoder has a control portion, a decoding portion and the like. The control portion determines the repeating number of times of the calculation for the second likelihood Ra to obtain the repeating number of times in association with the condition of the communication environment. The decoding portion decodes the error-correction code by using the repeating number of times determined at the control portion so that the decoded data is obtained efficiently by performing the decode so as to correspond to the condition of the communication environment.

### CROSS REFERENCE TO RELATED APPLICATION

This application is based upon Japanese Patent Application No. 2001-32618, filed on Oct. 24, 2001, the contents of which are incorporated herein by reference.

### BACKGROUND OF THE INVENTION

1. Field of the Invention

The present invention relates to a decoder for decoding an error-correcting code and a receiver using the same.

2. Related Art

A code error occurs easily in the mobile communication system. Therefore, a turbo encoder and a turbo decoder are suggested to be used.

The turbo encoder is employed in a radio wave transmitter to produce an error-correcting code of a information symbol based on the block data having plural information symbols as the information code. The turbo decoder obtains likelihood in each block data based on the error-correction code sent from the radio wave transmitter, and obtains the decode data based on the likelihood.

As shown in FIG. 1, the turbo encoder has a recursive convolution encoders 10 and 20, an interleaver 30, and a parallel/serial converter 40.

The block data constituted by the information symbols J(i) to J(i+2) ( “i” denotes an order of the information symbols) is input to the turbo encoder. The recursive convolution encoder 10 obtains a recursive organized code S(i) based on each information symbol in the block data.

The recursive organized code S(i) is constituted by the information symbol J(i), the delayed information symbol that is delayed for a predetermined time with respect to the information symbol J(i), and the further delayed information symbol that is delayed for a predetermined time with respect to the delayed information symbol.

The interleaver 30 changes the order of the information symbols J(i) to J(i+2) and outputs them. The recursive convolution encoder 20 obtains a recursive organized code U(i) based on the information symbols output from the interleaver 30.

The recursive organized code U(i) is constituted by the information symbol U(i), the delayed information symbol that is delayed for a predetermined time with respect to the information symbol U(i), and the further delayed information symbol that is delayed for a predetermined time with respect to the delayed information symbol.

The parallel/serial converter 40 is input with the information symbols constituting the block data as a organized code J(i), the recursive organized code S(i) and recursive organized code U(i). The parallel/serial converter 40 converts the organized code J(i), the recursive organized code S(i) and recursive organized code U(i) into error-correction codes of the serial data. The error-correction code is transmitted to the radio wave transmitter by being produced one after another from all of the information symbols in the block data.

Next, a turbo decoder will be described with reference to FIGS. 2 and 3.

The turbo decoder has a control portion 50 and a decoding portion 60. The decoding portion 60 obtains the likelihood of the information symbol, i.e., the decoded data. The decoding portion 60 has a serial/parallel converter 61, soft-determination decoders 62 and 63, an interleavers 64 and 65, a deinterleaver 66 and a soft determining portion 67. The likelihood means the probability of “1” being sent as the information symbol, or the probability of “0” being sent as the information symbol.

The serial/parallel converter 61, the soft-determination decoders 62 and 63, the interleavers 64 and 65, the deinterleaver 66 and the soft determining portion 67 are activated in accordance with direction sent from the control portion 50, respectively. These activations will be described with reference to FIG. 3.

First of all, the serial/parallel converter 61 performs a serial/parallel conversion of the error-correction code transmitted from the radio wave transmitter so as to output the organized code Ja(i) (=Ja(1), Ja(2), Ja(3)), the recursive organized code Sa(i) (=Sa(1), Sa(2), Sa(3)) and the recursive organized code Ua(i) (=Ua(1), Ua(2), Ua(3)) successively.

Next, the interleaver 64 changes the order of the organized code Ja(1)-Ja(3) so as to correspond to the order of the recursive organized code Ua(1)-Ua(3) at step 100. Hereinafter, the order-changed organized code Ja(1)-Ja(3) are referred to as organized code Jb(1), Jb(2), Jb(3), respectively.

After that, the calculation for the first likelihood P for the block data by using the soft-determination decoder 62 at steps 110 and 120, the order-change of the first likelihood P by using the interleaver 64 at step 130, the calculation for the second likelihood R for the block data by using the soft-determination decoder 63 at steps 140 and 150 and the order-change of the second likelihood R by using the interleaver 64 at step 160 are performed repeatedly for (X−1) times to obtain the second likelihood Ra(1, X−1), Ra(2, X−1), Ra(3, X−1). The flow will be followed by the X times calculation.

The soft-determination decoder 62 obtains the first likelihood P(1, X) based on the organized code Ja(1), the recursive organized code Sa(1) and the second likelihood Ra(1, X−1) at the (X−1)-time. Similarly, the first likelihood P(2, X) and the first likelihood P(3, X) are obtained based on the organized code Ja(2), the recursive organized code Sa(2) and the second likelihood Ra(2, X−1) at the (X−1)-time and the organized code Ja(3), the recursive organized code Sa(3) and the second likelihood Ra(3, X−1) at the (X−1)-time, respectively at steps 110 and 120.

Next, the interleaver 65 changes the order of the first likelihood P(1, X), P(2, X) and P(3, X) at step 130. Hereinafter, the first likelihood P(1, X), P(2, X) and P(3, X) are referred to as the first likelihood Pa(1, X), Pa(2, X) and Pa(3, X), respectively.

Next, the soft-determination decoder 63 obtains the second likelihood R(1, X) based on the organized code Jb(1), the recursive organized code Ua(1) and the first likelihood Pa(1, X−1). Similarly, the second likelihood R(2, X) and the second likelihood R(3, X) are obtained based on the organized code Jb(2), the recursive organized code Ua(2) and the first likelihood Pa (2, X−1) and the organized code Jb(3), the recursive organized code Ua(3) and the first likelihood Pa(3, X−1), respectively at steps 140 and 150.

Next, the deinterleaver 66 changes the order of the second likelihood R(1, X), R(2, X) and R(3, X) so as to correspond to the order of the organized code J(1), J(2) and J(3) at step 160. Hereinafter, the order-changed second likelihood R(1, X), R(2, X) and R(3, X) are referred to as second likelihood Ra(1, X), Ra(2, X) and Ra(3, X), respectively.

As described above, the accuracy of the second likelihood Ra(i, X) is improved by repeating the calculation for the second likelihood Ra for X times. The soft-determination portion 67 obtains the decoded data from the second likelihood Ra(i, X). Therefore, the decoded data becomes extremely precise. Accordingly, it is precisely determined which “0” or “1” is sent as the information symbol.

The repeating time X is fixed to a predetermined value in consideration of worse condition in communication environment between the radio wave transmitter and the radio wave receiver. However, the communication environment varies due to various reasons. Therefore, this fixed repeating of the calculation results in excess calculation as waste of process when the communication environment is good. This excess calculation lowers the process speed and efficiency.

### SUMMARY OF THE INVENTION

An object of the present invention is to provide a decoder capable of decoding efficiently and a receiver using the same.

According to a first aspect of the invention, a decoder has a decoding portion for decoding a received error-correction code using a parameter, an error calculating portion for calculating an error level of a known code, a parameter determining portion for determining the parameter based on the calculated error level.

The error level of the known code can denote the communication environment, and is a basis for the parameter. Therefore, the parameter is associated to the communication environment. Therefore, the received code can be decoded effectively by using this parameter.

Preferably, it is determined whether or not the error level is high as compared to a reference level. When the error level is high, the first value is used as the parameter. When the error level is not high, the second value is used as the parameter so that the decoding accuracy becomes low but the decoding speed becomes high.

The decoding portion may calculate the likelihood of the information code for a predetermined number of times based on the error-correction code and the likelihood of the previous-time information code, and obtain the decoded data based on the calculated likelihood of the information code.

The determining portion may regard the predetermined number of times as the parameter.

Namely, a repeating number of times for the calculation of the likelihood can be set to a value suitable for the communication environment by determining the repeating times based on the error level of the known code.

According to a second aspect of the present invention, a decoder, which is adopted to a receiver which digital-converts an error-correction code to an N-bit digital signal, has an error calculating portion for calculating an error level of a know code, a determining portion for determining whether or not the error level of the know code is equal to or higher than a reference value, a data setting portion for obtaining the digital data which has modified content of the N-bit digital signal so that L (L<N) bits of the N-bit digital signal from a LSB side of the signal are fixed to predetermined values, and a decoding portion performing a decode process based on the N-bit digital signal when the error level is equal to or higher than the reference level and performing a decode process based on the data obtained by the data setting portion when the error level is lower than the reference level.

With this feature, the signal is decoded in association with the error level so that the process speed of decoding can be faster when the level is lower than the reference level.

The data setting portion can be a data converting portion which converts the N-bit digital signal to a M-bit (M<N) digital data so that the process speed of decoding can be faster by performing the decode using the M-bit digital signal when the error level is lower than the reference level.

The above-described decoders can be adopted to a turbo decoder and to a receiver.

Other features and advantages of the resent invention will become more apparent from the following detailed description made with reference to the accompanying drawings.

### BRIEF DESCRIPTION OF THE DRAWINGS

FIG. 1 is a block diagram showing a turbo encoder of the related art;

FIG. 2 is a block diagram showing a turbo decoder of the related art;

FIG. 3 is a flow chart of the turbo decoder in FIG. 2;

FIG. 4 is a structure of a radio wave communication system of a first embodiment of the present invention;

FIG. 5 is a flow chart of a control portion in FIG. 4;

FIG. 6 is a flow chart of a control portion of a second embodiment of the present invention;

FIG. 7A is a sample of an N-bit digital data in the second embodiment of the present invention;

FIG. 7B is a sample of a modified N-bit digital data second embodiment of the present invention;

FIG. 7C is a sample of a M-bit digital data second embodiment of the present invention;

FIG. 8 is a block diagram showing a turbo decoder of a third embodiment of the present invention; and

FIG. 9 is a flow chart of a control portion in FIG. 8.

### DETAILED DESCRIPTION OF THE PREFERRED EMBODIMENT

Specific embodiments of the present invention will now be described hereinafter with reference to the accompanying drawings in which the same or similar component parts are designated by the same or similar reference numerals.

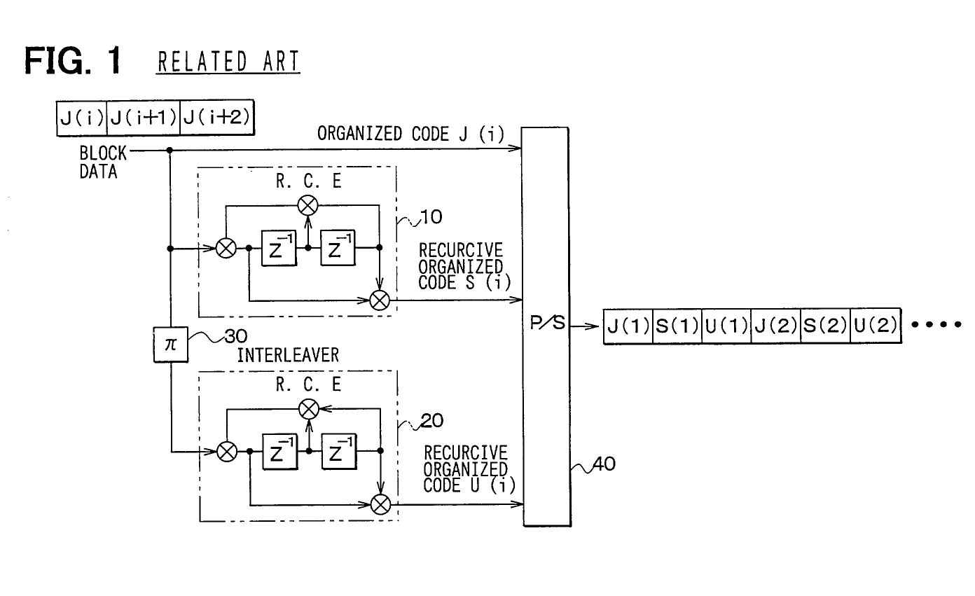

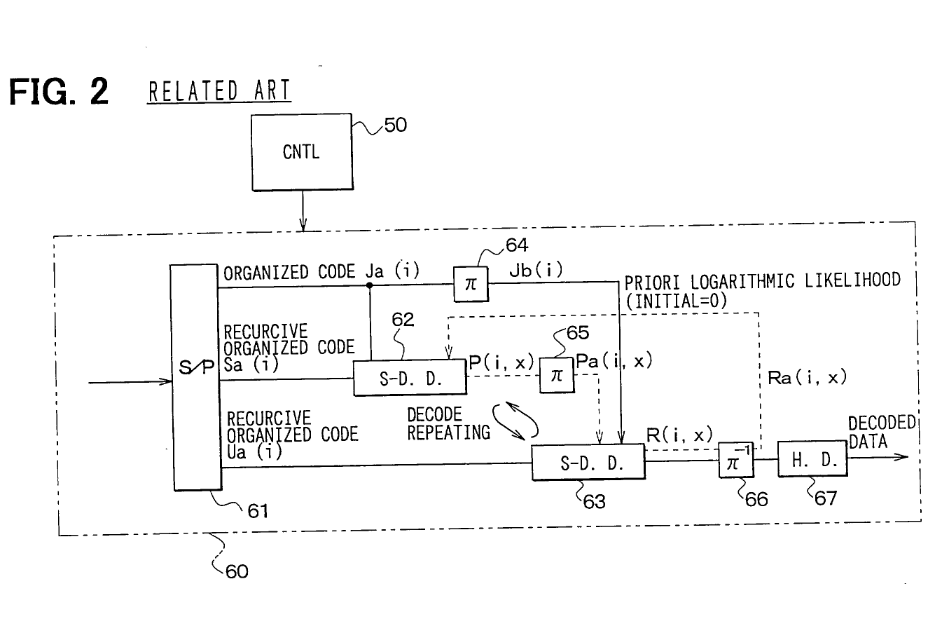

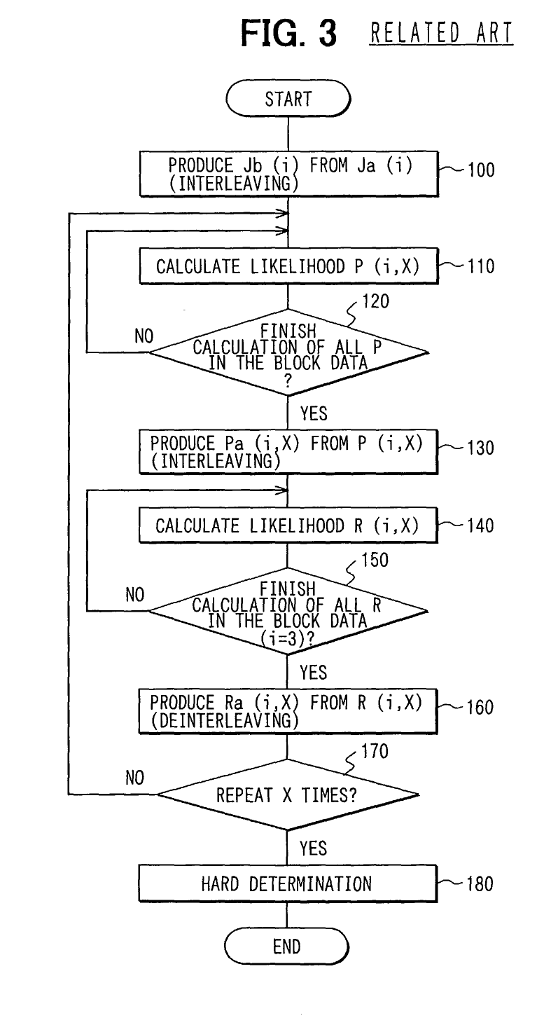

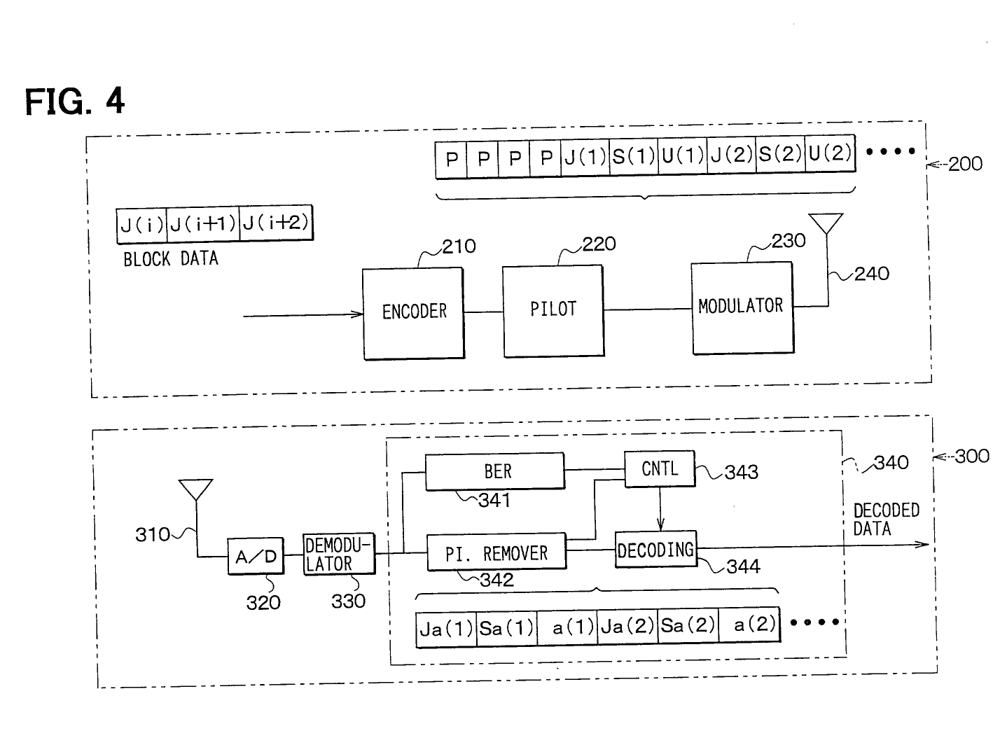

As shown in FIG. 4, a radio wave communication system has a transmitter 200 and a receiver 300. The transmitter 200 has a turbo encoder 210, a pilot adder 220, a modulator 230 and an antenna 240. The turbo encoder 210 has the same structure of the turbo encoder as shown in FIG. 1, that is, it produces an organized code J(i), recursive organized codes S(i) and U(i), and converts these codes to an error-correction code as the serial data.

The pilot adder 220 adds a pilot symbol (P: a known symbol as a known code) to the error-correction code of the serial data, and outputs it. The modulator 230 modulates the output signal from the pilot adder 220 and transmits it from the antenna 240.

The receiver 300 has an antenna 310, an A/D converter 320, a demodulator 330 and a turbo decoder 340. The antenna 310 and a receiver circuit (not shown) receive a transmitted signal from the transmitter 200. The A/D converter 320 converts the received signal as an analog signal into a digital signal.

The demodulator 330 demodulates the digital data output from the A/D converter 320 so that a N-bit pilot symbol and a N-bit error-correction code are obtained. Thus, an N-bit organized code Ja(i), an N-bit recursive organized code Sa(i), an N-bit recursive organized code Ua(i) are obtains.

The turbo decoder 340 has a BER measuring portion 341, a pilot removing portion 342, a control portion 343 and a decoding portion 344. The BER measuring portion 341 obtains a BER (Bit Error Rate) of the pilot symbol output from the A/D converter 320.

The pilot removing portion 342 removes each pilot symbol from output signals sent from the A/D converter 320, and then, outputs an error-correction code of a block data. The control portion 343 includes a microcomputer to determine a repeating number of times for a calculation of a second likelihood Ra, and orders the decoding portion 344 to decode using this repeating number of times. The decoding portion 344 has the same structure of the turbo decoder 60 as shown in FIG. 1, that is, it obtains the second likelihood Ra based on the organized code J(i), the recursive organized codes S(i) and U(i), and obtains a decoded data based on this second likelihood Ra.

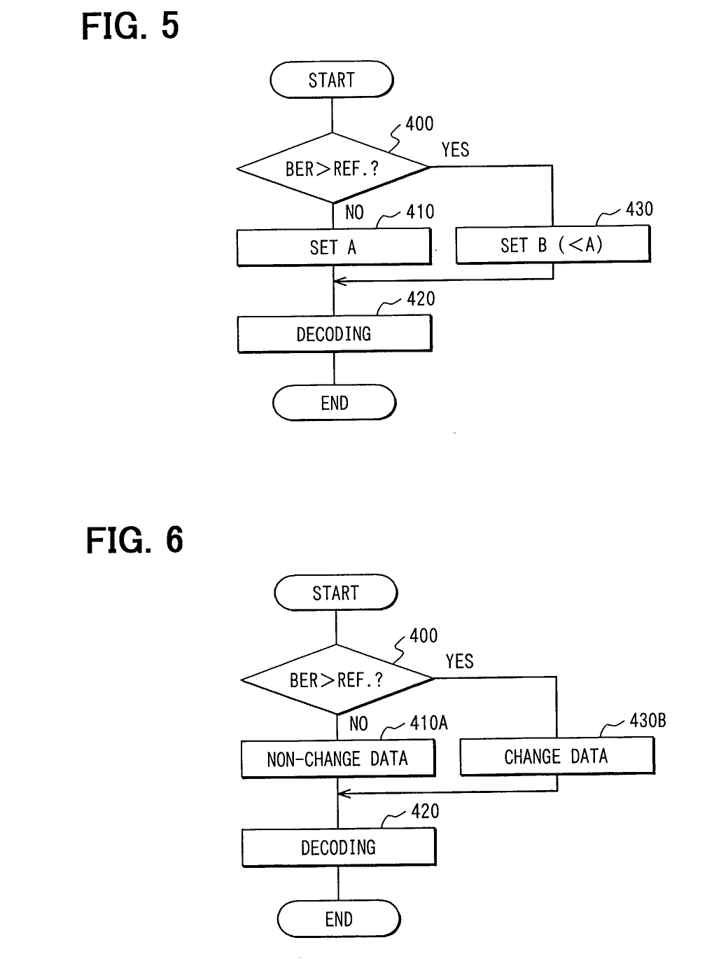

Hereinafter, a process for determining the repeating number of times of the calculation for the second likelihood Ra will be described with reference to a flow chart shown in FIG. 5. The control portion 343 performs a computer program in association with the flow chart shown in FIG. 5.

First of all, it is determined whether or not the BER (error rate) of the pilot symbol output from the BER measuring portion 341 is equal to or higher than a reference value (for example, 50%) at step 400. When the BER is equal to or higher than the reference value, the repeating number of times is set at A times at step 410. In this embodiment, the A times is obtained previously by performing a simulation in consideration of a bad condition of the communication environment.

Next, the calculation for the second likelihood Ra(i, X) is repeated for A times to obtain the second likelihood Ra(i, A), and the decoded data is calculated based on the second likelihood Ra(i, A) by the decoding portion 344 at step 420.

On the other hand, when the BER output from the BER measuring portion 341 is determined to be lower than the reference value at step 400, the repeating number of times is set at B times that is smaller than A at step 430. In this embodiment, the A times is obtained previously by performing a simulation in consideration of a good condition of the communication environment.

Next, the calculation for the second likelihood Ra(i, X) is repeated for A times to obtain the second likelihood Ra(i, B), and the decoded data is calculated based on the second likelihood Ra(i, B) by the decoding portion 344 at step 420.

As described above, the BER measuring portion 341 obtains the BER of the pilot symbol. Then, the control portion 343 determines the repeating number of times of the calculation for the second likelihood Ra(i, X) as a parameter. After that, the decoding portion 344 decodes the signal with the number of times of the calculation.

As described above, the repeating number of times of the calculation for the second likelihood Ra(i, X) can be obtained in association with the condition of the communication environment. Therefore, the error-correction code can be decoded efficiently by using this various repeating number of times. Moreover, the repeating number of times of the calculation for the second likelihood Ra(i, X) is varied according to the BER of the pilot symbol so that the error-correction code can be decoded while the precision in calculation for the second likelihood Ra(i, X), or the precision in decoding is restrained from deteriorating.

In the first embodiment, the decoder is the turbo decoder. However, this technique can be adopted to a decoder which performs the repeating calculation.

(Second Embodiment)

In the first embodiment, the example in which the error-correction code output from the pilot removing portion 342 is input to the decoding portion 344 to be decoded without changing is described. However, the error-correction code output from the pilot removing portion 342 can be changed.

A data modification process in the control portion 343 will be described with reference to a flow chart shown in FIG. 6. The data modification process will start when the N-bit error-correction code (digital data) is input from the pilot removing portion 342 to the control portion 343.

First, when it is determined that the BER is equal to or higher than the reference value, the decoder recognizes the communication environment is in bad condition, and performs the following process.

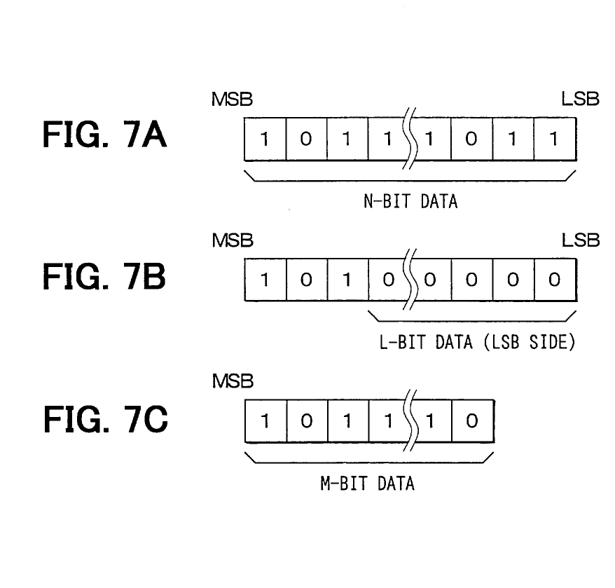

For example, when the N-bit error-correction code having a structure as shown in FIG. 7A as a content of the block data is input to the control portion 343, the control portion 343 inputs the N-bit error-correction code to the decoding portion 344 without changing it at step 410A. The decoder decodes this original error-correction code at step 420.

On the other hand, when it is determined that the BER is lower than the reference value, the decoder recognizes the communication environment is in bad condition, and performs the following process.

For example, when the N-bit error-correction code having a structure as shown in FIG. 7A as a content of the block data is input to the control portion 343, the control portion 343 sets each data in the L-bit data (L<N) of the N-bit error-correction code from its LSB side to a fixed constant value (for example, “0”) to produce the N-bit error-correction code as shown in FIG. 7B. The production of the new N-bit error-correction data which has fixed value in the content of its L-bit data from the LSB side is performed every N-bit error-correction data in a block data. The error-correction codes are decoded by the decoding portion 344 at step 420 based on all of the N-bit error-correction codes for the block data set at step 430B.

As described above, when the BER from the BER measuring portion 431 is lower than the reference value to thereby determining the communication environment is in good condition, the N-bit error-correction code whose L-bit data is fixed to the constant value is used to be decoded at the decoding portion 344. Therefore, the process speed becomes higher than that of the case using the N-bit error-correction code having data just sent from the pilot removing portion 342, i.e., the original N-bit error-correction code after being removed its pilot symbol at the pilot removing portion 342.

Although the error-correction code that have the constant value in the L-bit data from its LSB side has low precision as compared to the original error-correction code which is not changed, the error-correction code for decoding is changed in association with the BER of the pilot symbol so that the decoding is performed effectively while the precision of the decoding is restrained from deteriorating.

(Third Embodiment)

In the second embodiment, the example in which the N-bit error-correction code that have the constant value in the L-bit data from its LSB side is used for decoding is described. In this embodiment, a M-bit error-correction code whose size is smaller than the N-bit error-correction code (i.e., M<N) is produced from the N-bit error-correction code output from the pilot removing portion 342, and this M-bit error-correction code is used for decoding.

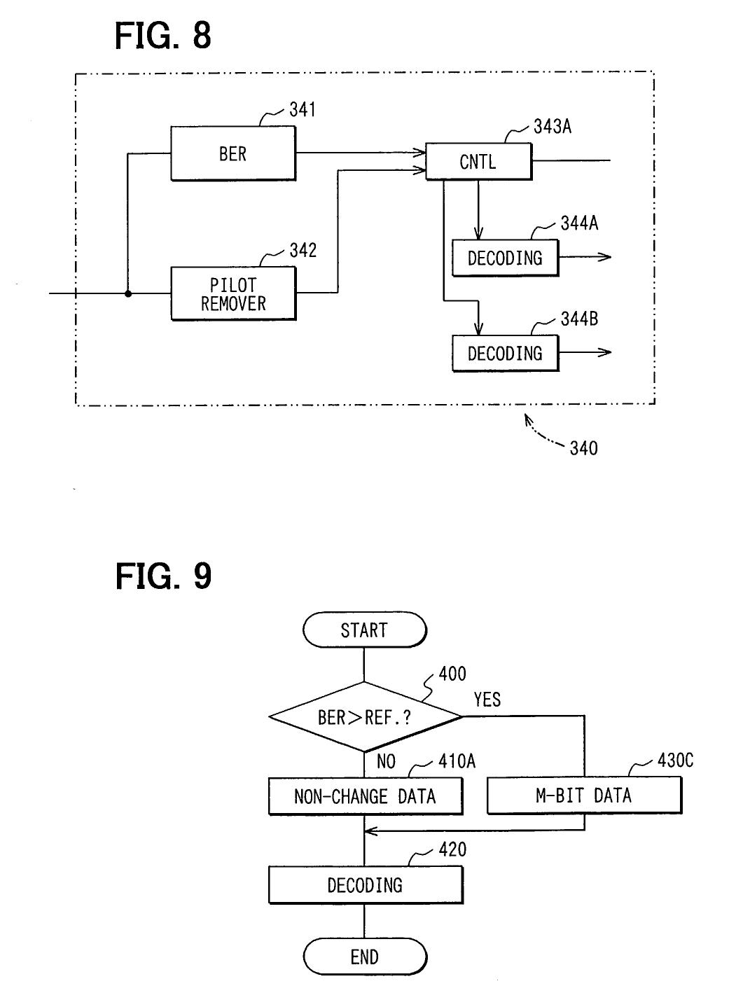

A turbo decoder 340 for this case is shown in FIG. 8. The turbo decoder 340 has a BER measuring portion 341, a pilot removing portion 342, a control portion 343A, and decoding portions 344A and 344B. Incidentally, the numerals same as those shown in FIG. 4 denotes the same or similar portions in FIG. 4.

The pilot removing portion 342 removes plural pilot symbols of the signals output from the A/D converter 320 to obtain only error-correction codes. In this embodiment, an error-correction output from the pilot removing portion 342 is an N-bit signal, and also digital data having an E(integer) number of decimals.

The decoding portion 344A obtains the decoded data based on an N-bit error-correction code having the E number of decimals while the decoding portion 344B obtains the decoded data based on a M-bit error-correction code having a F(integer) number of decimals. Wherein, the bit-number M is smaller than the bit-number N (M<N), the integer F is smaller than the integer E (F<E).

The control portion 343A receives the N-bit error-correction code from the pilot removing portion 342, and lets the decoding portions 344A and 344B decode the N-bit error-correction code or the M-bit error-correction code in association with the N-bit error-correction code. A detail flow of this process will be described with reference to FIG. 9.

First, when it is determined that the BER is equal to or higher than the reference value at step 400, the N-bit error-correction code for the block data that is not changed and sent from the pilot removing portion 342 is decoded by the decoding portion 344A at steps 410A and 420.

On the other hand, when it is determined that the BER is lower than the reference value, the control portion 343A performs the following process.

For example, when the N-bit error-correction code for the block data as shown in FIG. 7A is input to the control portion 343A from the pilot removing portion 342, the control portion 343A modifies the N-bit error-correction code to the M-bit error-correction code as shown in FIG. 7C. This modification means that the error-correction code having the E number of decimals is modified to the error-correction code having the E number of decimals at step 430C. After that, the modified error-correction code for the block data is decoded by the decoding portion 344A at step 420.

As described above, when the BER from the BER measuring portion 431 is lower than the reference value to thereby determining the communication environment is in good condition, the error-correction code having the F number of decimals is used for decoding at the decoding portion 344. Although the error-correction code having the F number of decimals has low precision as compared to the original error-correction code having the E number of decimals, the error-correction code for decoding is changed in association with the BER of the pilot symbol so that the decoding is performed effectively while the precision of the decoding is restrained from deteriorating.

Incidentally, the turbo decoder is employed in the second and third embodiment, the other type of the decoder can be used.

While the present invention has been shown and described with reference to the foregoing preferred embodiment, it will be apparent to those skilled in the art that changes in form and detail may be therein without departing from the scope of the invention as defined in the appended claims.

What is claimed is:

1. A decoder for being adopted to a receiver receiving a signal having an error-correction code and a known code of an information code comprising:
a decoding portion for decoding the received error-correction code using a parameter;
an error calculating portion for calculating an error level of the known code; and
a determining portion for determining said parameter based on the error level calculated at the error calculating portion.

2. A decoder according to claim 1, further comprising:
a determining means for determining whether or not the calculated error level is equal to or higher than a reference value, wherein said determining portion includes:
a first means for selecting a first value as said parameter when it is determined that the error level is equal to or higher than the reference value;
a second means for selecting a second value so that the precision in decoding is lower than that in decoding by using the first value as the parameter and a process speed in decoding is higher than that in decoding by using the first value as the parameter when it is determined that the error level is lower than the reference value.

3. A decoder according to claim 2, wherein:
the decoding portion repeats a calculation for obtaining the likelihood of said information code for a predetermined times by using said error-correction code and the previous likelihood of the information code obtained at a previous time, and obtains the decoded data based on the likelihood of the information code obtained by the calculation repeated for the predetermined times, and:
said determining portion determines said predetermined times as the parameter based on the calculated error level.

4. A decoder according to claim 3, wherein:
said first means selects a first number of times as said predetermined times when it is determined that the error level is equal to or higher than the reference value, and:
said second means selects a second number of times smaller than the first number of times as said predetermined times when it is determined that the error level is lower than the reference value.

5. A decoder for being adopted to a receiver receiving a signal having an error-correction code and a known code of an information code, and converting the error-correction code to an N-bit digital signal, comprising:
an error calculating portion for calculating an error level of the known code;
a determining means for determining whether or not the calculated error level is equal to or higher than a reference value;
a data setting means for obtaining the data having a constant value in the L-bit portion of the N-bit digital signal data from a LSB side of the N-bit digital signal, wherein a value of the L in the L-bit is smaller than that of the N in the N-bit; and
a decoding portion for decoding the N-bit digital signal when it is determined that the error level is equal to or higher than the reference value, and decoding the data obtained at the data setting means when it is determined that the error level is lower than the reference value.

6. A decoder for being adopted to a receiver receiving a signal having an error-correction code and a known code of an information code, and converting the error-correction code to an N-bit digital signal, comprising:
an error calculating portion for calculating an error level of the known code;
a determining means for determining whether or not the calculated error level is equal to or higher than a reference value;
a data modifying means for modifying the N-bit digital data to a M-bit digital data, wherein the value of the M in the M-bit is smaller than the value of the N in the N-bit; and
a decoding portion for decoding the N-bit digital signal when it is determined that the error level is equal to or higher than the reference value, and decoding the M-bit digital signal when it is determined that the error level is lower than the reference value.
